(19) United States
(12) Patent Application Publication
(10) Pub. No.: US 2026/0114093 A1
(43) Pub. Date: Apr. 23, 2026

(54) LIGHT EMITTING DEVICE

(71) Applicant: AGC Inc., Tokyo (JP)

(72) Inventors: Kazuo YAMADA, Tokyo (JP); Takenori SOMEYA, Haibara-gun (JP)

(73) Assignee: AGC Inc., Tokyo (JP)

(21) Appl. No.: 19/423,480

(22) Filed: Dec. 17, 2025

Related U.S. Application Data
(63) Continuation of application No. PCT/JP2024/020052, filed on May 31, 2024.

(30) Foreign Application Priority Data
Jun. 19, 2023 (JP) 2023-099791

(51) Int. Cl. H10H 20/855; H10H 20/84

(52) U.S. Cl. CPC H10H 20/855; H10H 20/84

(57) ABSTRACT

A light emitting device includes: a light emitting element that emits ultraviolet light having an emission peak wavelength of from 220 nm to 320 nm, and that has a radiant flux of higher than 20 mW; a first member; a second member; and a silicone resin layer that bonds the first member and the second member together, transmitting the ultraviolet light in this order. A first interface between the silicone resin layer and the first member has a shortest distance (A), from the center of the first interface to the peripheral edge of the first interface, of 1.00 mm or less. The thickness (B) of the silicone resin layer is 0.6 μm or more. The ratio (A/B) is 900 or less when the units are unified.

### CROSS-REFERENCE TO RELATED APPLICATIONS

This application is a continuation application of International Application No. PCT/JP2024/020052, filed on May 31, 2024, which is incorporated herein by reference in its entirety. Further, this application claims priority from Japanese Patent Application No. 2023-099791, filed on Jun. 19, 2023, the disclosure of which is incorporated by reference herein in their entirety.

### BACKGROUND

### Technical Field

The present disclosure relates to a light emitting device.

### Background Art

U.S. Pat. No. 10,074,784 and Japanese Patent No. 6817187 disclose light emitting devices that emit ultraviolet light. The light emitting device includes a light emitting element, a lens, and a silicone resin layer that bonds the light emitting element and the lens together. In U.S. Pat. No. 10,074,784, the radiant flux of the light emitting element is, for example, 1 mW. In Japanese Patent No. 6817187, the radiant flux of the light-emitting element is, for example, 15 mW or 20 mW. Radiant flux is the radiant energy emitted per unit time.

### SUMMARY

A light emitting device is known as including a first member, a second member, and a silicone resin layer that bonds the first member and the second member together. The first member, the silicone resin layer, and the second member transmit ultraviolet light in this order. In a case in which the emission peak wavelength of the ultraviolet light emitted by the light emitting element is short and the radiant flux of the light emitting element is strong, the silicone resin layer may become colored. As a result, the transmittance of ultraviolet light through the silicone resin layer may decrease, and the extraction efficiency of ultraviolet light may decrease.

One aspect of the present disclosure provides a technique that may suppress coloration of a silicone resin layer even if the emission peak wavelength of ultraviolet light emitted by the light emitting element is short and the radiant flux of the light emitting element is strong.

A light emitting device according to an aspect of the present disclosure includes: a light emitting element that emits ultraviolet light, an emission peak wavelength of the ultraviolet light being from 220 nm to 320 nm, and a radiant flux of the light emitting element being higher than 20 mW; and a first member, a second member, and a silicone resin layer that bonds the first member and the second member together, wherein: the first member, the silicone resin layer, and the second member transmit the ultraviolet light in this order, when viewed from a perpendicular direction relative to a first interface, which is an interface between the silicone resin layer and the first member, an entirety of the first interface is disposed within a periphery of a second interface, which is an interface between the silicone resin layer and the second member, the first interface has a shortest distance (A), from a center of the first interface to a peripheral edge of the first interface, of 1.00 mm or less, a thickness (B) of the silicone resin layer is 0.6 μm or more, and a ratio (A/B) of the shortest distance (A) from a center of the first interface to a peripheral edge of the first interface to the thickness (B) of the silicone resin layer when units are unified is 900 or less

According to an aspect of the present disclosure, even if the emission peak wavelength of the ultraviolet light emitted by the light emitting element is short and the radiant flux of the light emitting element is strong, coloration of the silicone resin layer may be suppressed.

### BRIEF DESCRIPTION OF THE DRAWINGS

FIG. 1 is a cross-sectional view illustrating a light emitting device according to an embodiment.

FIG. 2 is a plan view illustrating an example of the positional relationship between a first interface and a second interface.

FIG. 3 is a cross-sectional view illustrating an example of how a coloring component escapes from a silicone resin layer.

FIG. 4 is a cross-sectional view illustrating a first example of a test device.

FIG. 5 is a cross-sectional view illustrating a second example of a test device.

FIG. 6 is a cross-sectional view illustrating a third example of a test device.

FIG. 7 is a cross-sectional view illustrating a fourth example of a test device.

### DETAILED DESCRIPTION

Hereinafter, an embodiment of the present disclosure is explained with reference to the drawings. In addition, the same or corresponding configurations in the respective drawings are denoted by the same reference numerals, and description thereof may be omitted. In the present specification, the use of “to” to indicate a range of numerical values means that the values before and after “to” are included as the lower limit value and upper limit value (i.e., inclusive).

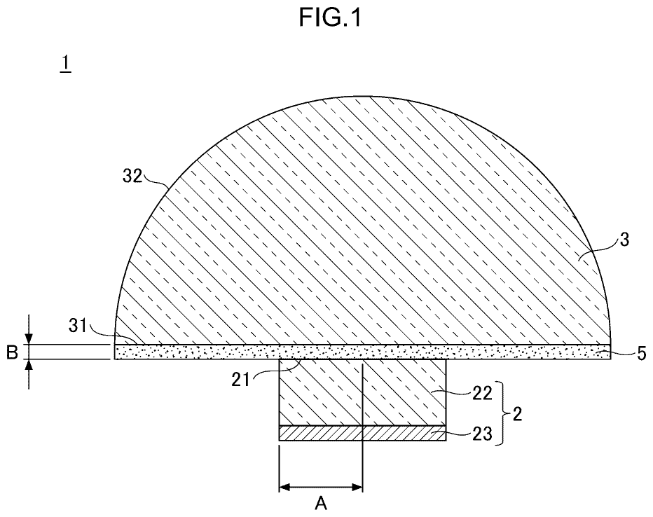

A light emitting device 1 according to an embodiment is described with reference to FIGS. 1 to 3. The light emitting device 1 includes a light emitting element 2, a lens 3, and a silicone resin layer 5 that bonds the light emitting element 2 and the lens 3 together. A part of the light emitting element 2 (specifically, for example, a substrate 22 described below) is an example of a first member, and the lens 3 is an example of a second member.

The light emitting element 2 emits ultraviolet light. A part of the light emitting element 2, the silicone resin layer 5, and the lens 3 transmit ultraviolet light in this order. The emission peak wavelength of the ultraviolet light is, for example, 220 nm to 320 nm, and preferably 260 nm to 290 nm. The “emission peak wavelength” is the wavelength at which the output value is highest in the spectral distribution of the emitted light. Further, the radiant flux of the light emitting element 2 is, for example, more than 20 mW, preferably 35 mW or more, and more preferably 40 mW or more. From the viewpoint of heat dissipation of the light emitting element 2, the radiant flux of the light emitting element 2 may be 120 mW or less. Radiant flux is the radiant energy emitted per unit time. Radiant flux is measured in accordance with CIE 127:2007.

The light emitting element 2 includes, for example, a substrate 22 and a semiconductor layer 23. The light emitting element 2 has, for example, a flip chip structure. When the light emitting element 2 has a flip chip structure, ultraviolet light generated at the semiconductor layer 23 is emitted through the substrate 22. The substrate 22 is a transparent substrate that transmits ultraviolet light. The surface of the substrate 22 facing the lens 3 is the light emitting surface 21 of the light emitting element 2.

The substrate 22 is made from, for example, a sapphire substrate or an aluminum nitride substrate. The aluminum nitride substrate is a substrate made from a single crystal of aluminum nitride. The sapphire substrate or aluminum nitride substrate is a transparent substrate that transmits ultraviolet light. The thickness t of the substrate 22 is, for example, 0.05 mm to 2 mm.

The semiconductor layer 23 is provided at the opposite side of the substrate 22 from the lens 3. The semiconductor layer 23 emits light when a voltage is applied. Although not illustrated, an electrode for applying a voltage to the semiconductor layer 23 is formed on the opposite side of the semiconductor layer 23 from the substrate 22 so as not to block the ultraviolet light traveling from the semiconductor layer 23 toward the substrate 22. Therefore, it is possible to prevent a reduction in light extraction efficiency.

The light emitting element 2 may be bonded to a mounting substrate via solder bumps. The mounting substrate is, for example, a ceramic substrate made of sintered aluminum nitride, sintered aluminum oxide, or a low temperature co-fired ceramic (LTCC), on which an electrode is formed.

The lens 3 suppresses total reflection of the ultraviolet light and improves the extraction efficiency of the ultraviolet light. The lens 3 has an opposing surface 31 facing the light emitting surface 21 of the light emitting element 2, and a convex curved surface 32 facing away from the opposing surface 31. The ultraviolet light emitted by the light emitting element 2 is incident on the opposing surface 31 and exits from the convex curved surface 32. The convex curved surface 32 is a dome-shaped curved surface whose center protrudes more than its peripheral edge.

The lens 3 may be a spherical lens or an aspherical lens. Although not illustrated, the lens 3 may have a flange that protrudes radially outward from the peripheral edge of the convex curved surface 32.

Although not illustrated, the convex curved surface 32 of the lens 3 may have unevenness to prevent reflection of the ultraviolet light generated by the light emitting element 2. The unevenness of the convex curved surface 32 has, for example, a moth-eye structure, which prevents ultraviolet light traveling from the inside of the lens 3 to the outside from being reflected back into the lens 3, thereby improving the efficiency of ultraviolet light extraction.

Although not illustrated, the light emitting device 1 may be provided with an anti-reflection film on the convex curved surface 32 of the lens 3. The anti-reflection film prevents ultraviolet light traveling from the inside of the lens 3 to the outside from being reflected back into the lens 3, thereby improving the efficiency of ultraviolet light extraction. As the anti-reflection film, a general anti-reflection film is used.

Although not illustrated, the convex curved surface 32 of the lens 3 may have unevenness that scatters the ultraviolet light generated by the light emitting element 2. The unevenness of the convex curved surface 32 scatters the ultraviolet light emitted from the convex curved surface 32, thereby emitting the ultraviolet light over a wider range.

The lens 3 is made of, for example, oxide glass. Oxide glass may be processed by various processing methods such as thermal forming or grinding and polishing, and a processing method suited to the shape of the lens 3 may be selected. The oxide glass is, for example, soda-lime glass, alkali-free glass, chemically strengthened glass, or lanthanum borate glass. In order to reduce the loss of ultraviolet light through the lens 3, a material with low ultraviolet light absorption rate is suitable as the material of the lens 3, and the material of the lens 3 is preferably quartz, quartz glass, or sapphire.

The silicone resin layer 5 bonds the light emitting surface 21 of the light emitting element 2 and the opposing surface 31 of the lens 3 such that they face each other. It is preferable that the light emitting surface 21 of the light emitting element 2 and the opposing surface 31 of the lens 3 each have a flat surface at least in the area at which they are stacked together. The opposing surface 31 of the lens 3 is larger than the light emitting surface 21 of the light emitting element 2, and the area of the opposing surface 31 extending beyond the light emitting surface 21 may have a curved surface.

The surface roughness Ra of the light emitting surface 21 of the light emitting element 2 is, for example, 0.01 nm to 5 nm. In a case in which a fine uneven structure is formed at the light emitting surface 21 in order to improve the efficiency of ultraviolet light extraction, the surface roughness Ra of the light emitting surface 21 is 5 nm to 50 nm. The surface roughness Ra of the opposing surface 31 of the lens 3 is, for example, 0.01 nm to 5 nm. The surface roughness Ra is the arithmetic mean roughness as described in JIS B0601:2001.

Incidentally, the shorter the emission peak wavelength of the ultraviolet light emitted by the light emitting element 2, the more easily the silicone resin layer 5 becomes colored. Furthermore, the stronger the radiant flux of the light emitting element 2, the more easily the silicone resin layer 5 becomes colored. If the silicone resin layer 5 becomes colored, the transmittance of ultraviolet light decreases, and the efficiency of ultraviolet light extraction decreases.

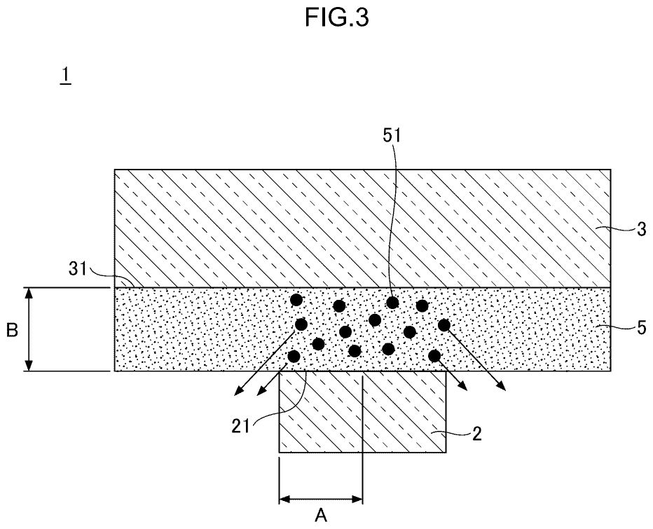

The present inventors have found that coloring of the silicone resin layer 5 may be suppressed by adjusting the size of the light emitting surface 21 and the thickness of the silicone resin layer 5, even in a case in which the emission peak wavelength of the ultraviolet light emitted by the light emitting element 2 is short and the radiant flux of the light emitting element 2 is large. In a case in which the emission peak wavelength of the ultraviolet light emitted by the light emitting element 2 is large or the radiant flux of the light emitting element 2 is small, it is thought that the size of the light emitting surface 21 and the thickness of the silicone resin layer 5 do not affect the coloring of the silicone resin layer 5. The inventors of the present application have found that even if the emission peak wavelength of the ultraviolet light is 220 nm to 320 nm and the radiant flux of the light-emitting element 2 exceeds 20 mW, if the conditions described below are met, as illustrated in FIG. 3, it is presumed that a coloring component 51 of the silicone resin layer 5 is likely to escape from the silicone resin layer 5 into the surrounding atmosphere (e.g., an air atmosphere or nitrogen atmosphere), and the silicone resin layer 5 is resistant to coloration. The conditions for suppressing coloration of the silicone resin layer 5 are explained below.

The interface between the silicone resin layer 5 and the light emitting element 2 is called a first interface. In the present embodiment, the first interface is the entire light emitting surface 21, but it may be one part of the light emitting surface 21. Further, the interface between the silicone resin layer 5 and the lens 3 is called a second interface. In the present embodiment, the second interface is the entire opposing surface 31, but it may be one part of the opposing surface 31.

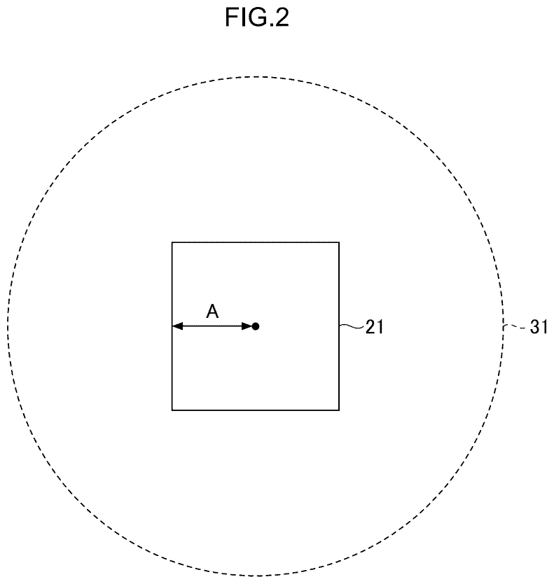

As illustrated in FIG. 2, when viewed from a direction perpendicular to the light emitting surface 21, the entire light emitting surface 21 is disposed within the periphery of the opposing surface 31. Therefore, the length of a path along which the coloring component 51 of the silicone resin layer 5 escapes from the silicone resin layer 5 into the surrounding atmosphere can be represented by the shortest distance (A) from the center of the light emitting surface 21 to the peripheral edge of the light emitting surface 21.

In a case in which the light emitting surface 21 is square, the half value of the length of one side of the square is the shortest distance (A). Note that the shape of the light emitting surface 21 is not limited to a square.

The shortest distance (A) is preferably 1.00 mm or less. If the shortest distance (A) is 1.00 mm or less, the length of the path along which the coloring component 51 escapes from the silicone resin layer 5 into the surrounding atmosphere is short, and coloring of the silicone resin layer 5 may be suppressed. The shortest distance (A) is more preferably 0.50 mm or less. From the viewpoint of the intensity of the radiant flux, the shortest distance (A) is preferably 0.20 mm or more.

As illustrated in FIG. 3, the width of the path along which the coloring component 51 escapes from the silicone resin layer 5 into the surrounding atmosphere can be represented by the thickness (B) of the silicone resin layer 5. Further, the aspect ratio of the path along which the coloring component 51 escapes from the silicone resin layer 5 to the surrounding atmosphere (the ratio of the path length to the path width) can be represented by the ratio (A/B) when the units of the shortest distance (A) and the thickness (B) are unified.

The thickness (B) is preferably 0.6 μm or more. If the thickness (B) is 0.6 μm or more, the light emitting element 2 and the lens 3 may be bonded together. The thickness (B) is more preferably 1.2 μm or more, and even more preferably 2.0 μm or more. The thickness (B) is preferably as large as possible from the viewpoint of adhesiveness and suppression of coloration, but may be 10 μm or less.

The ratio (A/B) is preferably 900 or less. If the ratio (A/B) is 900 or less, the aspect ratio of the above-mentioned path is small, the coloring component 51 easily escapes, and coloring of the silicone resin layer 5 may be suppressed. The ratio (A/B) is more preferably 550 or less, and even more preferably 390 or less. From the viewpoint of suppressing coloration, the ratio (A/B) is preferably as small as possible, but may be 50 or more.

The silicone resin has an organosiloxy unit. The organosiloxy unit includes: a monofunctional organosiloxy unit, referred to as an M unit; a difunctional organosiloxy unit, referred to as a D unit; a trifunctional organosiloxy unit, referred to as a T unit; and a tetrafunctional organosiloxy unit, referred to as a Q unit. While the Q unit is a unit that does not have an organic group bonded to a silicon atom (i.e., an organic group having a carbon atom bonded to a silicon atom), in the present specification, it is regarded as an organosiloxy unit (i.e., silicon-containing bond unit). Monomers forming M units, D units, T units, and Q units are also referred to as M monomers, D monomers, T monomers, and Q monomers, respectively.

In the present specification, the term “total organosiloxy units” refers to the total of M units, D units, T units, and Q units. The ratio of the number (molar amount) of M units, D units, T units, and Q units can be calculated from the peak area ratio value by 29Si-NMR.

In the organosiloxy unit, a siloxane bond is a bond in which two silicon atoms are bonded via one oxygen atom, as a result of which the number of oxygen atoms per silicon atom in the siloxane bond is regarded as 1/2, and is expressed in formulae as O_{1/2}. More specifically, for example, in one D unit, one silicon atom is bonded to two oxygen atoms, and each oxygen atom is bonded to a silicon atom of another unit, as a result of which the formula is —O_{1/2}—(R)₂Si—O_{1/2}— (where R represents a hydrogen atom or an organic group). Since there are two instances of O_{1/2}, the D unit is usually expressed as (R)₂SiO_{2/2} (in other words, (R)₂SiO).

In the following explanation, an oxygen atom O* bonded to another silicon atom is an oxygen atom bonding two silicon atoms together, and refers to the oxygen atom in the bond represented by Si—O—Si. Therefore, one instance of O* is present between the silicon atoms of two organosiloxy units.

An M unit refers to an organosiloxy unit represented by (R)₃SiO_{1/2}. Here, R represents a hydrogen atom or an organic group. The number (here, 3) indicated after (R) indicates that three hydrogen atoms or organic groups are bonded to the silicon atom. That is, the M unit has one silicon atom, three hydrogen atoms or organic groups, and one oxygen atom O*. More specifically, the M unit has three hydrogen atoms or organic groups bonded to one silicon atom and an oxygen atom O* bonded to one silicon atom.

A D unit refers to an organosiloxy unit represented by (R)₂SiO_{2/2} (where R represents a hydrogen atom or an organic group). That is, the D unit is a unit that has one silicon atom, two hydrogen atoms or organic groups bonded to the silicon atom, and two oxygen atoms O* bonded to another silicon atom.

A T unit refers to an organosiloxy unit represented by RSiO_{3/2} (where R represents a hydrogen atom or an organic group). That is, the T unit is a unit that has one silicon atom, one hydrogen atom or organic group bonded to the silicon atom, and three oxygen atoms O* bonded to another silicon atom.

A Q unit refers to an organosiloxy unit represented by SiO₂. That is, the Q unit is a unit that has one silicon atom and four oxygen atoms O* bonded to another silicon atom.

Examples of the organic group include an alkyl group, an aryl group, an aralkyl group, and a halogen-substituted monovalent hydrocarbon group. The alkyl group is, for example, a methyl group, an ethyl group, a propyl group, a butyl group, a pentyl group, a hexyl group, a cyclohexyl group, or a heptyl group. The aryl group is, for example, a phenyl group, a tolyl group, a xylyl group, or a naphthyl group. The aralkyl group is, for example, a benzyl group or a phenethyl group. The halogen-substituted monovalent hydrocarbon group is, for example, a halogenated alkyl group. The halogenated alkyl group is, for example, a chloromethyl group, a 3-chloropropyl group, or a 3,3,3-trifluoropropyl group. The organic group is preferably an unsubstituted or halogen-substituted monovalent hydrocarbon group having 1 to 12 carbon atoms (preferably about 1 to 10 carbon atoms).

In view of durability with respect to ultraviolet light, the silicone resin configuring the silicone resin layer 5 preferably contains at least one specific organosiloxy unit selected from the group consisting of organosiloxy units represented by RSiO_{3/2} (T units) and organosiloxy units represented by SiO₂ (Q units).

The proportion of the specific organosiloxy units is preferably 60 mol % or more based on the total of organosiloxy units, and is more preferably 80 mol % or more. While there is no particular upper limit, it is often 100 mol % or less. The ratio of the number (molar amount) of T units, and Q units can be calculated from the peak area ratio value by 29Si-NMR.

Silicone resins are usually obtained by curing (crosslinking and curing) curable silicones. That is, the silicone resin corresponds to a cured product of a curable silicone. While curable silicones are classified as condensation reaction type silicones, addition reaction type silicones, ultraviolet curing type silicones, and electron beam curing type silicones, depending on their curing mechanism, any of these may be used.

While the method for forming the silicone resin layer 5 is not particularly limited, spin coating, spray coating, bar coating, gravure coating, screen printing, inkjet coating, or the like may be used, for example. Further, a method may be used in which a silicone resin layer formed on a support member such as a release film is transferred to an optical member such as a light emitting element or a lens.

In order to bond the optical member and the light emitting element 2 with sufficient adhesive strength using the silicone resin layer 5, it is preferable to thoroughly clean the surfaces of the optical member and the light emitting element 2 to be bonded. While the cleaning method is not particularly limited, cleaning may be performed using, for example, hydrocarbon solvents such as ethanol and acetone, fluorine-based solvents such as AS-300 (manufactured by AGC Inc.), or a water-based cleaner such as an alkaline detergent. Further, the adhesive strength can be improved by subjecting the surfaces to be bonded to a surface activation treatment. For example, UV ozone treatment, atmospheric pressure plasma treatment, excimer UV treatment, corona treatment, or the like may be used.

While the process for bonding the optical member and the light emitting element 2 is not particularly limited, in addition to a method of bonding the optical member and the light emitting element 2 under atmospheric pressure, for example, a method of bonding them in a vacuum may be used. Further, in order to facilitate the bonding, the optical member and the light emitting element 2 may be attached together while being heated.

In order to obtain sufficient adhesive strength, heat treatment or autoclave treatment (heating and pressurizing treatment) or the like may be performed after bonding the optical member and the light emitting element 2 together. Furthermore, after bonding, the silicone resin layer 5 may be subjected to aging treatment by causing the light emitting element 2 to emit light. The above-mentioned heat treatment, autoclave treatment and aging treatment may be carried out in an atmospheric pressure atmosphere or in an inert gas atmosphere.

### EXAMPLES

Experimental data is explained below. The following Examples 1 to 4, 6 to 9, 13, 15 and 16 are working examples, and the following Examples 5, 10 to 12, 14, and 17 to 20 are comparative examples.

### Example 1

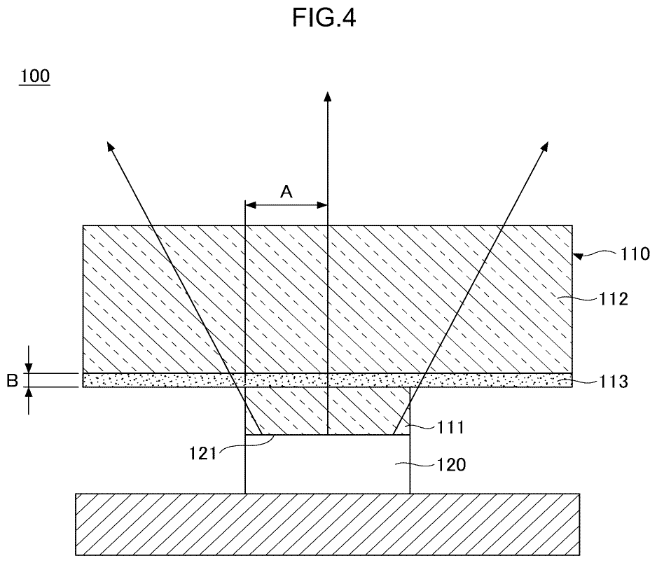

In Example 1, as illustrated in FIG. 4, a test device 100 was fabricated by placing a layered body 110 on a light emitting surface 121 of a light emitting element 120. While the layered body 110 is described in detail below, it was fabricated by bonding a first quartz substrate 111 and a second quartz substrate 112 with a silicone resin layer 113. An interface between the first quartz substrate 111 and the silicone resin layer 113 is a first interface, and an interface between the second quartz substrate 112 and the silicone resin layer 113 is a second interface. The first quartz substrate 111 had a square main surface with sides of 0.8 mm, and a thickness of 0.17 mm. The shortest distance (A) between the center of the first interface and the peripheral edge of the first interface was 0.40 mm. The second quartz substrate 112 had a square main surface with sides of 5 mm, and a thickness of 0.5 mm. The layered body 110 was placed on the light emitting element 120 with the first quartz substrate 111 facing downward. After the test device 100 was fabricated in this manner, the light emitting device 120 was continuously lit at 70° C. for 500 hours, and changes in the radiant flux (W) of ultraviolet light emitted from the layered body 110 were measured. The radiant flux of the ultraviolet light emitted from the layered body 110 was measured using an integrating sphere. The light emitting element 120 emitted ultraviolet light with an emission peak wavelength of 265 nm, the light emitting surface 121 was a square with sides of 0.8 mm, and the radiant flux of the light emitting element 120 was 40 mW. The radiant flux of the light emitting element 120 was measured without placing the layered body 110 on the light emitting surface 121 of the light emitting element 120.

The layered body 110 was fabricated by the following procedure. First, the organic adhesive solution A1 described below was applied by spin coating to the surface of a 50 μm-thick PET film (Cosmoshine® A4160 manufactured by Toyobo Co., Ltd.), and heating was performed at 100° C. for 5 minutes using a hot plate, to thereby form the silicone resin layer 113. Next, the silicone resin layer 113 was attached to a surface of the second quartz substrate 112, and subjected to a heating and pressurizing treatment at 1.0 MPa and 120° C. for 10 minutes using an autoclave treatment device. Next, the silicone resin layer 113 was cooled to room temperature, and then the PET film was peeled off. Subsequently, the second quartz substrate 112 with the silicone resin layer 113 attached thereto was heated at 150° C. for 30 minutes using an oven. Thereafter, the first quartz substrate 111 was overlaid on the silicone resin layer 113 and heated at 200° C. for 30 minutes using an oven, thereby producing the layered body 110. The thickness (B) of the silicone resin layer 113 was 2.0 μm.

The organic adhesive solution A1 was prepared by the following procedure. First, triethoxymethylsilane (179 g), toluene (300 g), and acetic acid (5 g) were placed in a flask stirred at 25° C. for 20 minutes, further heated to 60° C., and reacted for 12 hours, to obtain a crude reaction liquid. Next, the crude reaction liquid was cooled to 25° C. and then washed three times with water (300 g). Next, toluene was distilled off from the crude reaction liquid under reduced pressure to prepare a slurry. The slurry was then dried overnight in a vacuum dryer to obtain a white organopolysiloxane compound (resin A2). A mixed liquid obtained by mixing the resin A2 and toluene was filtered using a filter with a pore size of 0.45 μm to prepare the organic adhesive solution A1.

### Example 2

In Example 2, a test device 100 having the same structure as Example 1 was fabricated, except that the thickness (B) of the silicone resin layer 113 was changed to 4.0 μm, and similarly to Example 1, changes in the radiant flux of ultraviolet light emitted from the layered body 110 were measured.

### Example 3

In Example 3, a test device 100 having the same structure as Example 1 was fabricated, except that the thickness (B) of the silicone resin layer 113 was changed to 1.0 μm, and similarly to Example 1, changes in the radiant flux of ultraviolet light emitted from the layered body 110 were measured.

### Example 4

In Example 4, a test device 100 having the same structure as Example 1 was fabricated, except that the thickness (B) of the silicone resin layer 113 was changed to 0.8 μm, and similarly to Example 1, changes in the radiant flux of ultraviolet light emitted from the layered body 110 were measured.

### Example 5

In Example 5, a test device 100 having the same structure as Example 1 was fabricated, except that the thickness (B) of the silicone resin layer 113 was changed to 0.2 μm, and similarly to Example 1, changes in the radiant flux of ultraviolet light emitted from the layered body 110 were measured.

### Example 6

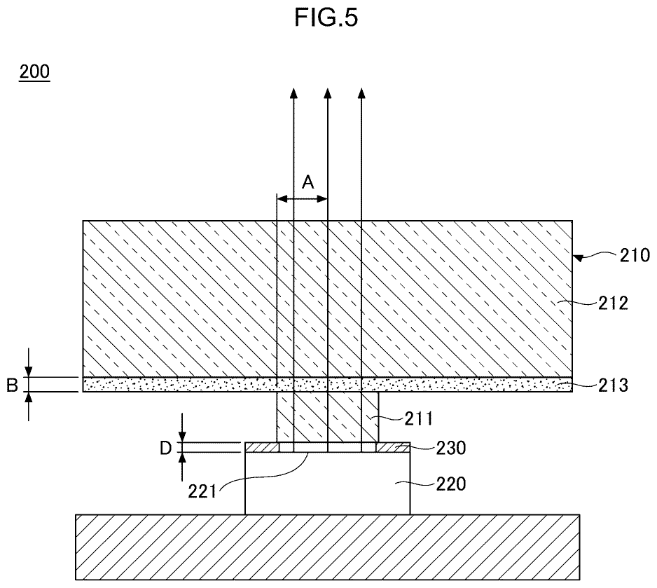

In Example 6, as illustrated in FIG. 5, a test device 200 was fabricated by placing a rectangular frame-shaped aluminum sheet 230 and a layered body 210 in this order on a light emitting surface 221 of a light emitting element 220. The layered body 210 was fabricated by bonding a first quartz substrate 211 and a second quartz substrate 212 with a silicone resin layer 213, similarly to the layered body 110. The interface between the first quartz substrate 211 and the silicone resin layer 213 is the first interface, and the interface between the second quartz substrate 212 and the silicone resin layer 213 is the second interface. The first quartz substrate 211 had a square main surface with sides of 0.6 mm, and a thickness of 0.17 mm. The shortest distance (A) between the center of the first interface and the peripheral edge of the first interface was 0.29 mm. The second quartz substrate 212 had a square main surface with sides of 5 mm, and a thickness of 0.5 mm. The thickness (B) of the silicone resin layer 213 was 2.0 μm. The thickness of the aluminum sheet 230 was 12 μm, and the opening in the aluminum sheet 230 was a square with sides of 0.5 mm. The layered body 210 was placed on the light emitting element 220 via the aluminum sheet 230 with the first quartz substrate 211 facing downward. Between the light emitting element 220 and the first quartz substrate 211, an air layer having the same thickness as the aluminum sheet 230 was formed. The thickness (D) of the air layer was 0.012 mm. After the test device 200 was fabricated in this manner, the light emitting element 220 was continuously lit at 70° C. for 500 hours, and changes in the radiant flux (W) of ultraviolet light emitted from the layered body 210 were measured. The radiant flux of the ultraviolet light emitted from the layered body 210 was measured using an integrating sphere. The light emitting element 220 emitted ultraviolet light with an emission peak wavelength of 265 nm, the light emitting surface 221 was a square with a length of 0.8 mm and a width of 0.8 mm, and the radiant flux of the light emitting element 220 was 60 mW. The radiant flux of the light emitting element 220 was measured without placing the aluminum sheet 230 and the layered body 210 on the light emitting surface 221 of the light emitting element 220.

### Example 7

In Example 7, a test device 200 having the same structure as in Example 6 was fabricated except that the length of one side of the opening of the aluminum sheet 230 was changed to 0.3 mm, the shortest distance (A) between the center of the first interface and the peripheral edge of the first interface was changed to 0.19 mm by changing the length of one side of the main surface of the first quartz substrate 211 to 0.4 mm, and the radiant flux of the light emitting element 220 was changed to 80 mW, and similarly to Example 6, changes in the radiant flux of ultraviolet light emitted from the layered body 210 were measured.

### Example 8

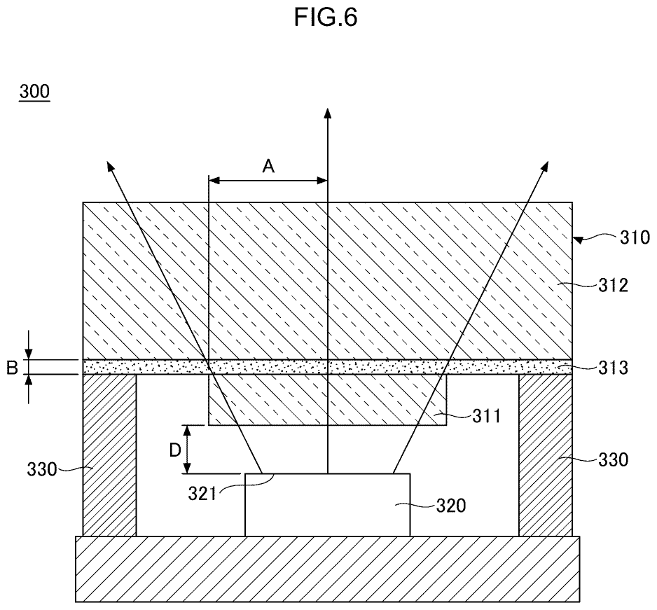

In Example 8, as illustrated in FIG. 6, a test device 300 was fabricated by disposing a layered body 310 above a light emitting element 320 with a space therebetween. The layered body 310 was fabricated by bonding a first quartz substrate 311 and a second quartz substrate 312 with a silicone resin layer 313, similarly to the layered body 110. The interface between the first quartz substrate 311 and the silicone resin layer 313 is the first interface, and the interface between the second quartz substrate 312 and the silicone resin layer 313 is the second interface. The first quartz substrate 311 had a square main surface with sides of 1.2 mm, and a thickness of 0.17 mm. The shortest distance (A) between the center of the first interface and the peripheral edge of the first interface was 0.59 mm. The second quartz substrate 312 had a square main surface with sides of 5 mm, and a thickness of 0.5 mm. The thickness (B) of the silicone resin layer 313 was 2.0 μm. The layered body 310 was formed by placing the first quartz substrate 311 facing downwards and the silicone resin layer 313 on a spacer 330 so as to form an air layer between the first quartz substrate 311 and the light emitting element 320. The thickness (D) of the air layer was 0.050 mm. After the test device 300 was fabricated in this manner, the light emitting element 320 was continuously lit at 70° C. for 500 hours, and changes in the radiant flux (W) of ultraviolet light emitted from the layered body 310 were measured. The radiant flux of the ultraviolet light emitted from the layered body 310 was measured using an integrating sphere. The light emitting element 320 emitted ultraviolet light with an emission peak wavelength of 265 nm, the light emitting surface 321 was a square with sides of 0.8 mm, and the radiant flux of the light emitting element 320 was 80 mW. The radiant flux of the light emitting element 320 was measured without disposing the layered body 310 above the light emitting surface 321 of the light emitting element 320. Further, by setting the thickness (D) of the air layer to 0.050 mm, it was possible to irradiate the entire first interface with ultraviolet light.

### Example 9

In Example 9, a test device 300 having the same structure as in Example 8 was fabricated except that the shortest distance (A) between the center of the first interface and the peripheral edge of the first interface was changed to 0.77 mm by changing the length of one side of the main surface of the first quartz substrate 311 to 1.5 mm, and the thickness of the air layer (D) was changed to 0.100 mm by changing the thickness of the spacer 330, and similarly to Example 8, changes in the radiant flux of ultraviolet light emitted from the layered body 310 were measured. Further, by setting the thickness (D) of the air layer to 0.100 mm, it was possible to irradiate the entire first interface with ultraviolet light.

### Example 10

In Example 10, a test device 300 having the same structure as in Example 8 was fabricated except that the shortest distance (A) between the center of the first interface and the peripheral edge of the first interface was changed to 1.15 mm by changing the length of one side of the main surface of the first quartz substrate 311 to 2.3 mm, and the thickness of the air layer (D) was changed to 0.200 mm by changing the thickness of the spacer 330, and similarly to Example 8, changes in the radiant flux of ultraviolet light emitted from the layered body 310 were measured. Further, by setting the thickness (D) of the air layer to 0.200 mm, it was possible to irradiate the entire first interface with ultraviolet light.

### Example 11

In Example 11, a test device 300 having the same structure as Example 10 was fabricated, except that the radiant flux of the light-emitting element 320 was changed to 40 mW, and similarly to Example 10, changes in the radiant flux of ultraviolet light emitted from the layered body 310 were measured.

### Example 12

In Example 12, a test device 300 having the same structure as in Example 8 was fabricated except that the shortest distance (A) between the center of the first interface and the peripheral edge of the first interface was changed to 1.33 mm by changing the length of one side of the main surface of the first quartz substrate 311 to 2.7 mm, and the thickness of the air layer (D) was changed to 0.250 mm by changing the thickness of the spacer 330, and similarly to Example 8, changes in the radiant flux of ultraviolet light emitted from the layered body 310 were measured. Further, by setting the thickness (D) of the air layer to 0.250 mm, it was possible to irradiate the entire first interface with ultraviolet light.

### Example 13

In Example 13, a test device 300 having the same structure as in Example 8 was fabricated except that the shortest distance (A) between the center of the first interface and the peripheral edge of the first interface was changed to 0.77 mm by changing the length of one side of the main surface of the first quartz substrate 311 to 1.5 mm, the thickness of the air layer (D) was changed to 0.100 mm by changing the thickness of the spacer 330, and the thickness (B) of the silicone resin layer 313 was changed to 1.5 μm, and similarly to Example 8, changes in the radiant flux of ultraviolet light emitted from the layered body 310 were measured. Further, by setting the thickness (D) of the air layer to 0.100 mm, it was possible to irradiate the entire first interface with ultraviolet light.

### Example 14

In Example 14, a test device 300 having the same structure as in Example 8 was fabricated except that the shortest distance (A) between the center of the first interface and the peripheral edge of the first interface was changed to 0.77 mm by changing the length of one side of the main surface of the first quartz substrate 311 to 1.5 mm, the thickness of the air layer (D) was changed to 0.100 mm by changing the thickness of the spacer 330, and the thickness (B) of the silicone resin layer 313 was changed to 0.8 μm, and similarly to Example 8, changes in the radiant flux of ultraviolet light emitted from the layered body 310 were measured. Further, by setting the thickness (D) of the air layer to 0.100 mm, it was possible to irradiate the entire first interface with ultraviolet light.

### Example 15

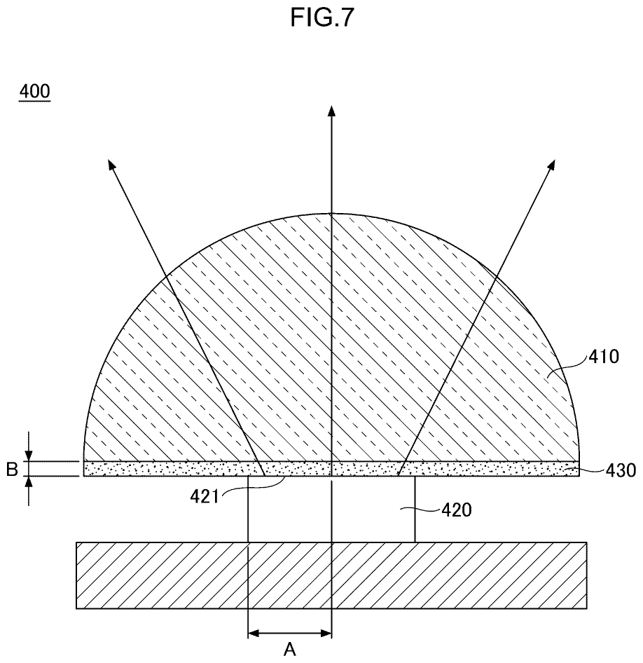

In Example 15, as illustrated in FIG. 7, a test device 400 was fabricated by bonding a hemispherical quartz lens 410 and a light emitting element 420 with a silicone resin layer 430. The test device 400 was fabricated according to the following procedure. First, the organic adhesive solution A1 described above was applied by spin coating to the surface of a 50 μm-thick PET film (Cosmoshine® A4160 manufactured by Toyobo Co., Ltd.), and heating was performed at 100° C. for 5 minutes using a hot plate, to thereby form the silicone resin layer 430. Next, the silicone resin layer 430 is bonded to the flat surface of the hemispherical quartz lens 410 (which is circular with a diameter of 3 mm), and heating and pressurizing treatment was performed at 1.0 MPa and 120° C. for 10 minutes using an autoclave treatment device. Next, the silicone resin layer 430 was cooled to room temperature, and then the PET film was peeled off. Subsequently, the quartz lens 410 with the silicone resin layer 430 attached thereto was heated at 150° C. for 30 minutes using an oven. Thereafter, the light emitting element 420 was overlaid on the silicone resin layer 430 and heated at 200° C. for 30 minutes using an oven, to thereby produce the test device 400. The interface between the light emitting element 420 and the silicone resin layer 430 is a first interface, and the interface between the quartz lens 410 and the silicone resin layer 430 is a second interface. The shortest distance (A) between the center of the first interface and the peripheral edge of the first interface was 0.40 mm. The thickness (B) of the silicone resin layer 430 was 2.0 μm. After the test device 400 was fabricated in this manner, the light emitting element 420 was continuously lit for 500 hours at 70° C., and changes in the radiant flux (W) of ultraviolet light emitted from the convex curved surface of the quartz lens 410 were measured. The radiant flux of the ultraviolet light emitted from the convex curved surface of the quartz lens 410 was measured using an integrating sphere. The light emitting element 420 emitted ultraviolet light with an emission peak wavelength of 265 nm, the light emitting surface 421 was a square with sides of 0.8 mm, and the radiant flux of the light emitting element 420 was 40 mW. The radiant flux of the light emitting element 420 was measured without the silicone resin layer 430 and the quartz lens 410 being placed on the light emitting surface 421 of the light emitting element 420.

### Example 16

In Example 16, a test device 400 having the same structure as Example 15 was fabricated, except that the thickness (B) of the silicone resin layer 430 was changed to 4.0 μm, and similarly to Example 15, changes in the radiant flux of ultraviolet light emitted from the convex curved surface of the quartz lens 410 were measured.

### Example 17

In Example 17, a test device 400 having the same structure as Example 15 was fabricated, except that the thickness (B) of the silicone resin layer 430 was changed to 0.5 μm, and similarly to Example 15, changes in the radiant flux of ultraviolet light emitted from the convex curved surface of the quartz lens 410 were measured.

### Example 18

In Example 18, a test device 400 having the same structure as in Example 15 was fabricated except that the shortest distance (A) between the center of the first interface and the peripheral edge of the first interface was changed to 0.50 mm by changing the length of one side of the light emitting surface 421 to 1.0 mm, and the radiant flux of the light emitting element 420 was changed to 8 mW, and similarly to Example 15, changes in the radiant flux of ultraviolet light emitted from the convex curved surface of the quartz lens 410 were measured.

### Example 19

In Example 19, a test device 400 having the same structure as in Example 15 was fabricated except that the shortest distance (A) between the center of the first interface and the peripheral edge of the first interface was changed to 1.60 mm by changing the length of one side of the light emitting surface 421 to 3.2 mm, and the radiant flux of the light emitting element 420 was changed to 12 mW, and similarly to Example 15, changes in the radiant flux of ultraviolet light emitted from the convex curved surface of the quartz lens 410 were measured.

### Example 20

In Example 20, a test device 400 having the same structure as in Example 15 was fabricated except that the shortest distance (A) between the center of the first interface and the peripheral edge of the first interface was changed to 1.60 mm by changing the length of one side of the light emitting surface 421 to 3.2 mm, and the radiant flux of the light emitting element 420 was changed to 20 mW, and similarly to Example 15, changes in the radiant flux of ultraviolet light emitted from the convex curved surface of the quartz lens 410 were measured.

### Evaluation Results

The evaluation results for Examples 1 to 20 are shown in Table 1. In Table 1, the “radiant flux maintenance rate” indicates the ratio (%) of the radiant flux at the end of lighting to the radiant flux at the start of lighting. The higher the radiant flux maintenance rate, the higher the transparency of the silicone resin layer and the lower the coloring of the silicone resin layer. In Table 1, “∘” under “Adhesion Strength” indicates that adhesion was possible, and “x” under “Adhesion Strength” indicates that adhesion was not possible.

Further, in Table 1, “∘” under “Evaluation” indicates that the radiant flux maintenance rate was 90% or more and adhesion was possible. “Δ” under “Evaluation” indicates that the radiant flux maintenance rate was 80% or more but less than 90% and adhesion was possible. “x” under “Evaluation” indicates that the radiant flux maintenance rate was less than 80% or that adhesion was not possible.

TABLE 1

| | | Radiant | | | | | Radiant Flux | | |
|---|---|---|---|---|---|---|---|---|---|
| | Testing | Flux | D | A | B | | Maintenance | Adhesion | |
| | Device | [mW] | [mm] | [mm] | [μm] | A/B | Rate | Strength | Evaluation |
| Example 1 | FIG. 4 | 40 | — | 0.40 | 2.0 | 200 | 92 | ∘ | ∘ |
| Example 2 | FIG. 4 | 40 | — | 0.40 | 4.0 | 100 | 97 | ∘ | ∘ |
| Example 3 | FIG. 4 | 40 | — | 0.40 | 1.0 | 400 | 85 | ∘ | Δ |
| Example 4 | FIG. 4 | 40 | — | 0.40 | 0.8 | 500 | 82 | ∘ | Δ |
| Example 5 | FIG. 4 | 40 | — | 0.40 | 0.2 | 2000 | — | x | x |
| Example 6 | FIG. 5 | 60 | 0.012 | 0.29 | 2.0 | 147 | 95 | ∘ | ∘ |
| Example 7 | FIG. 5 | 80 | 0.012 | 0.19 | 2.0 | 97 | 99 | ∘ | ∘ |
| Example 8 | FIG. 6 | 80 | 0.050 | 0.59 | 2.0 | 293 | 91 | ∘ | ∘ |
| Example 9 | FIG. 6 | 80 | 0.100 | 0.77 | 2.0 | 387 | 90 | ∘ | ∘ |
| Example 10 | FIG. 6 | 80 | 0.200 | 1.15 | 2.0 | 573 | 73 | ∘ | x |
| Example 11 | FIG. 6 | 40 | 0.200 | 1.15 | 2.0 | 573 | 78 | ∘ | x |
| Example 12 | FIG. 6 | 80 | 0.250 | 1.33 | 2.0 | 667 | 65 | ∘ | x |
| Example 13 | FIG. 6 | 80 | 0.100 | 0.77 | 1.5 | 515 | 80 | ∘ | Δ |
| Example 14 | FIG. 6 | 80 | 0.100 | 0.77 | 0.8 | 967 | 70 | ∘ | x |
| Example 15 | FIG. 7 | 40 | — | 0.40 | 2.0 | 200 | 90 | ∘ | ∘ |
| Example 16 | FIG. 7 | 40 | — | 0.40 | 4.0 | 100 | 95 | ∘ | ∘ |
| Example 17 | FIG. 7 | 40 | — | 0.40 | 0.5 | 800 | — | x | x |
| Example 18 | FIG. 7 | 8 | — | 0.50 | 2.0 | 250 | 90 | ∘ | — |
| Example 19 | FIG. 7 | 12 | — | 1.60 | 2.0 | 800 | 92 | ∘ | — |
| Example 20 | FIG. 7 | 20 | — | 1.60 | 2.0 | 800 | 92 | ∘ | — |

According to Examples 1 to 4, 6 to 9, 13, 15 and 16, unlike Examples 5, 10 to 12, and 14, since (A) was 1.00 mm or less, (B) was 0.6 μm or more, and (A/B) was 900 or less, the radiant flux maintenance rate was 80% or more and adhesion was possible. Further, according to Examples 1, 2, 6 to 9, 15 and 16, since (A) was 1.00 mm or less, (B) was 0.6 μm or more, and (A/B) was 390 or less, the radiant flux maintenance rate was 90% or more and adhesion was possible.

Examples 18 to 20 are examples in which the radiant flux of the light emitting element is 20 mW or less. In Examples 19 and 20, the radiant flux of the light emitting element was larger than in Example 18, and (A) was larger than 1.00 mm; however, the radiant flux maintenance rate was 90% or more, as in Example 18. It can be understood that in a case in which the radiant flux of the light emitting element is 20 mW or less, (A) and (A/B) have almost no effect on the radiant flux maintenance rate.

The following supplementary notes are disclosed regarding the above-described embodiments.

### [Supplementary Note 1]

A light emitting device, including:
a light emitting element that emits ultraviolet light, an emission peak wavelength of the ultraviolet light being from 220 nm to 320 nm, and a radiant flux of the light emitting element being higher than 20 mW; and
a first member, a second member, and a silicone resin layer that bonds the first member and the second member together, in which:
the first member, the silicone resin layer, and the second member transmit the ultraviolet light in this order,
when viewed from a perpendicular direction relative to a first interface, which is an interface between the silicone resin layer and the first member, an entirety of the first interface is disposed within a periphery of a second interface, which is an interface between the silicone resin layer and the second member,
the first interface has a shortest distance (A), from a center of the first interface to a peripheral edge of the first interface, of 1.00 mm or less,
a thickness (B) of the silicone resin layer is 0.6 μm or more, and
a ratio (A/B) of the shortest distance (A) from a center of the first interface to a peripheral edge of the first interface to the thickness (B) of the silicone resin layer when units are unified is 900 or less.

### [Supplementary Note 2]

The light emitting device of supplementary note 1, in which the ratio (A/B) of the shortest distance (A) from the center of the first interface to the peripheral edge of the first interface to the thickness (B) of the silicone resin layer when units are unified is 550 or less.

### [Supplementary Note 3]

The light emitting device of supplementary note 1, in which the ratio (A/B) of the shortest distance (A) from the center of the first interface to the peripheral edge of the first interface to the thickness (B) of the silicone resin layer when units are unified is 390 or less.

### [Supplementary Note 4]

The light emitting device of any one of supplementary notes 1 to 3, in which the ratio (A/B) of the shortest distance (A) from the center of the first interface to the peripheral edge of the first interface to the thickness (B) of the silicone resin layer when units are unified is 50 or more.

### [Supplementary Note 5]

The light emitting device of any one of supplementary notes 1 to 4, in which the shortest distance (A) from the center of the first interface to the peripheral edge of the first interface is 0.50 mm or less.

### [Supplementary Note 6]

The light emitting device of any one of supplementary notes 1 to 5, in which the thickness (B) of the silicone resin layer is 2.0 μm or more.

### [Supplementary Note 7]

The light emitting device of any one of supplementary notes 1 to 6, in which the silicone resin layer includes at least one type of specific organosiloxy unit selected from the group consisting of T units and Q units.

### [Supplementary Note 8]

The light emitting device of supplementary note 7, in which a proportion of the specific organosiloxy unit is 60 mol % or more relative to a total of organosiloxy units.

### [Supplementary Note 9]

The light emitting device of any one of supplementary notes 1 to 8, in which the radiant flux of the light emitting element is 35 mW or more.

### [Supplementary Note 10]

The light emitting device of any one of supplementary notes 1 to 9, in which the emission peak wavelength of the ultraviolet light is from 260 nm to 290 nm.

### [Supplementary Note 11]

The light emitting device of any one of supplementary notes 1 to 10, in which the first member is a part of the light emitting element.

### [Supplementary Note 12]

The light emitting device of any one of supplementary notes 1 to 11, in which the second member is a lens.

While the light emitting device according to the present disclosure has been described above, the present disclosure is not limited to the embodiments described above. Various changes, modifications, substitutions, additions, deletions, and combinations are possible within the scope recited in the claims. Of course, these also fall within the technical scope of the present disclosure.

What is claimed is:

1. A light emitting device, comprising:
a light emitting element that emits ultraviolet light, an emission peak wavelength of the ultraviolet light being from 220 nm to 320 nm, and a radiant flux of the light emitting element being higher than 20 mW; and
a first member, a second member, and a silicone resin layer that bonds the first member and the second member together, wherein:
the first member, the silicone resin layer, and the second member transmit the ultraviolet light in this order,
when viewed from a perpendicular direction relative to a first interface, which is an interface between the silicone resin layer and the first member, an entirety of the first interface is disposed within a periphery of a second interface, which is an interface between the silicone resin layer and the second member,
the first interface has a shortest distance (A), from a center of the first interface to a peripheral edge of the first interface, of 1.00 mm or less,
a thickness (B) of the silicone resin layer is 0.6 μm or more, and
a ratio (A/B) of the shortest distance (A) from a center of the first interface to a peripheral edge of the first interface to the thickness (B) of the silicone resin layer when units are unified is 900 or less.

2. The light emitting device of claim 1, wherein the ratio (A/B) of the shortest distance (A) from the center of the first interface to the peripheral edge of the first interface to the thickness (B) of the silicone resin layer when units are unified is 550 or less.

3. The light emitting device of claim 1, wherein the ratio (A/B) of the shortest distance (A) from the center of the first interface to the peripheral edge of the first interface to the thickness (B) of the silicone resin layer when units are unified is 390 or less.

4. The light emitting device of claim 1, wherein the ratio (A/B) of the shortest distance (A) from the center of the first interface to the peripheral edge of the first interface to the thickness (B) of the silicone resin layer when units are unified is 50 or more.

5. The light emitting device of claim 1, wherein the shortest distance (A) from the center of the first interface to the peripheral edge of the first interface is 0.50 mm or less.

6. The light emitting device of claim 1, wherein the thickness (B) of the silicone resin layer is 2.0 μm or more.

7. The light emitting device of claim 1, wherein the silicone resin layer includes at least one type of specific organosiloxy unit selected from the group consisting of T units and Q units.

8. The light emitting device of claim 7, wherein a proportion of the specific organosiloxy unit is 60 mol % or more relative to a total of organosiloxy units.

9. The light emitting device of claim 1, wherein the radiant flux of the light emitting element is 35 mW or more.

10. The light emitting device of claim 1, wherein the emission peak wavelength of the ultraviolet light is from 260 nm to 290 nm.

11. The light emitting device of claim 1, wherein the first member is a part of the light emitting element.

12. The light emitting device of claim 1, wherein the second member is a lens.
